(19) United States
(12) Patent Application Publication
(10) Pub. No.: US 2012/0301999 A1
(43) Pub. Date: Nov. 29, 2012

(54) METHOD OF MANUFACTURING AN AMORPHOUS/CRYSTALLINE SILICON HETEROJUNCTION SOLAR CELL

(75) Inventors: Mario TUCCI, Roma (IT); Simona DE IULIIS, Petten (NL); Lambert Johan GEERLIGS, Petten (NL); Luca SERENELLI, Roma (IT); Enrico SALZA, Roma (IT); Luisa PIROZZI, Roma (IT); Domenico CAPUTO, Roma (IT); Giampiero DE CESARE, Roma (IT)

(73) Assignee: STICHTING ENERGIEONDERZOEK CENTRUM NEDERLAND, LE Petten (NL)

(21) Appl. No.: 13/566,159

(22) Filed: Aug. 3, 2012

Related U.S. Application Data
(63) Continuation of application No. 12/128,109, filed on May 28, 2008.

(51) Int. Cl. H01L 31/075

(52) U.S. Cl. 438/72; 257/E31.061

(57) ABSTRACT

A method for manufacturing a solar cell includes
providing a first conductivity type doped crystalline silicon wafer,
depositing on one side a first intrinsic a-Si:H buffer layer, followed by a second conductivity type doped a-Si:H layer,
turning over the wafer and depositing on the opposite side a surface passivating anti-reflection coating,
applying a first mask having a grid opening on the second conductivity type doped a-Si:H covered surface of the wafer,
dry etching to remove the second conductivity type doped a-Si:H layer not covered by the first mask,
while maintaining the first mask in position:
   depositing a second intrinsic buffer layer of a-Si:H,
   depositing a first conductivity type doped a-Si:H layer.

### CROSS REFERENCE TO RELATED APPLICATIONS

This application is a continuation of copending application Ser. No. 12/128,109 filed on May 28, 2008. The entire contents of the above-identified application are hereby incorporated by reference.

### FIELD

The present invention relates to a method for manufacturing a solar cell. Also, the present invention relates to a solar cell comprising an emitter and a back surface field as rear-junctions with back side contacting.

### BACKGROUND

Recently, there has been renewed industrial interest in high efficiency silicon solar cells. This interest is motivated by the large leveraging effect that higher cell efficiency has in reducing overall photovoltaic costs.

Top performing production cells are SunPower's A-300 cell [1], and Sanyo's HIT cell [2]; both technologies have demonstrated cell efficiencies of almost 22%., starting from n-type monocrystalline silicon wafers. The advantages of high efficiency silicon solar cells include reduced silicon cost on a per-watt basis (g/Wp) and, reduced per-watt module construction and installation costs (Euro/Wp), although these savings are offset by the more complicated processing required [3,4]. Finally higher module efficiency leads to lower PV system costs, because installation and material costs are somewhat dependent on module area. The back-contact technology allows improvement of the module active area fraction. The temperature coefficient of high Voc cells is better than conventional c-Si solar cells and results in a higher output power at high temperatures [5].

In the SunPower's A-300 cell design interdigitated n+ and p+ diffusions and grid lines are used to collect photogenerated carriers entirely from the back of the cell. Key design features that contribute to high efficiency include: localized back contacts, which reduce contact recombination losses; a grid-less front surface, which permits optimization of light trapping and passivation; and a back-side metallization approach that provides internal rear-surface reflection and very low series resistance losses [6,7]. On the other hand, the number of processing steps is quite large and includes three high temperature steps. Sunpower has identified recombination at the contacts as a major limiting factor to obtaining even higher efficiency, individuating the heterojunction as a possible way of improvement [8].

Sanyo's HIT structure enables an excellent surface passivation of c-Si (crystalline Silicon) surface defects by high-quality intrinsic a-Si:H layers. The complete surface, including the contacts, is passivated. This results in high efficiency, especially a high Voc: almost 730 mV has been reached [5,9]. The low-temperature processes (<200° C.) and the symmetrical structure of HIT cells can suppress both thermal and mechanical stress during its production process and results in an advantage for thinner c-Si wafers. Key approaches for obtaining a higher Voc are considered to be as follows: clean c-Si surface before a-Si:H deposition (a-Si: amorphous Silicon), deposition of high-quality intrinsic a-Si:H layer, lower plasma and/or thermal damage to the c-Si surface during a-Si:H, and optimization of the band offset of the a-Si:H/c-Si interface [10].

One of the problems of the a-Si:H/c-Si heterostructure is a loss of quantum efficiency in the blue region of the solar spectrum due to the absorption of the front side a-Si:H window layer. Additionally, the front side a-Si:H has to be covered with a thin conductive oxide which results in absorption loss in the IR region.

### SUMMARY

It is an object of the present invention to provide a method for manufacturing a solar cell with improved efficiency over the prior art.

The object is achieved by a method for manufacturing a solar cell, comprising

providing a first conductivity type doped crystalline silicon wafer,

depositing on one side a first intrinsic a-Si:H buffer layer, followed by an second conductivity type doped a-Si:H layer,

turning over the wafer and depositing on the opposite side a surface passivating anti-reflection coating

applying a first mask having a grid opening on the second conductivity type doped a-Si:H covered surface of the wafer,

dry etching to remove the second conductivity type doped a-Si:H layer not covered by the first mask,

while maintaining the first mask in position:
depositing a second intrinsic buffer layer of a-Si:H,
depositing a first conductivity type doped a-Si:H layer.

According to an aspect of the invention, the method further comprises:

depositing a first contact material layer on the first conductivity type doped a-Si:H layer, while maintaining the first mask in position.

According to an aspect of the invention, the method further comprises:

applying a second mask and depositing through the second mask a second contact material layer on the second conductivity type doped a-Si:H layer.

According to an aspect of the invention, the first mask has a comb shaped grid opening.

According to an aspect of the invention, applying the second mask is performed by rotating the first mask over 180 degrees on the wafer.

According to an aspect of the invention, the first conductivity type is p-type and the second conductivity type is n-type.

According to an aspect of the invention, the first conductivity type is n-type and the second conductivity type is p-type.

According to an aspect of the invention, the first contact material layer on the first conductivity type doped a-Si:H layer is Al.

According to an aspect of the invention, the second contact material layer on the second conductivity type doped a-Si:H layer is Ag.

According to an aspect of the invention, wherein the first contact material/layer on the first conductivity type doped a-Si:H layer and the second contact material/layer on the second conductivity type doped a-Si:H layer are comb shaped.

According to an aspect of the invention, the first contact material layer on the first conductivity type doped a-Si:H layer and the second contact material/layer on the second conductivity type doped a-Si:H layer are interdigitated.

According to an aspect of the invention, the surface passivating anti-reflection coating is an a-Si:H/SiNx double layer.

According to an aspect of the invention, the one side of the crystalline silicon wafer is a polished side of the wafer.

According to an aspect of the invention, the distance between adjacent fingers of the interdigitated combs is dimensioned supposed to the diffusion length of minority photo generated carriers.

According to an aspect of the invention, the diffusion length is in the order of 400 μm.

According to an aspect of the invention, processing is performed at temperature below 300° C.

According to an aspect of the invention, there is provided a solar cell comprising an emitter and a back surface field as rear-junctions with back side contacting, and a grid-less front surface passivated by a surface passivating anti-reflection coating; the emitter and the back surface field both formed by a a-Si:H/c-Si heterostructures, the back side contacting of the emitter being interdigitated with the backside contacting of the back surface field, wherein the solar cell comprises a first conductivity type doped crystalline silicon wafer;

on the one side an intrinsic a-Si:H buffer layer, followed by an second conductivity type doped a-Si:H layer; the solar cell on the second conductivity type doped a-Si:H covered surface of the wafer comprising a grid opening to the intrinsic a-Si:H buffer layer or to the c-Si substrate, in which opening a stack is located of an intrinsic buffer layer of a-Si:H and a first conductivity type doped a-Si:H layer.

According to an aspect of the invention there is provided a solar cell, wherein a contact of a first contact material is located on the first conductivity type doped a-Si:H layer of the stack.

According to an aspect of the invention there is provided a solar cell, wherein a contact of a second contact material is located on the second conductivity type doped a-Si:H layer.

According to an aspect of the invention there is provided a solar cell, wherein the surface passivating anti-reflection coating on the side opposite the one side comprises an a-Si:H/SiNx double layer.

### BRIEF DESCRIPTION OF DRAWINGS

The invention will be explained in more detail below with reference to a few drawings in which illustrative embodiments of the invention are shown. It will be appreciated by the person skilled in the art that other alternative and equivalent embodiments of the invention can be conceived and reduced to practice without departing from the true spirit of the invention, the scope of the invention being limited only by the appended claims.

FIGS. 1a-1g show a schematic view of the fabrication process;

FIG. 2 shows I-V measurements and photovoltaic parameters under AM1.5G condition after laser treatment, experimental data (symbols) and PC1D simulation (lines), and

FIG. 3 shows IQE, EQE, Reflectance of the cell, experimental data (symbols) and PC1D simulation (line).

### DETAILED DESCRIPTION OF EMBODIMENTS

To increase the open circuit voltage and the efficiency of amorphous/crystalline (a-Si:H/c-Si) silicon heterostructure solar cells, both the emitter fabrication and the back surface field formation have recently received new interest. These technological processes can be performed in a PECVD system at temperature below 350° C. Here we show how the heterostructure technology can have a chance in the challenge of back side contacted solar cell. In an embodiment, the device is formed starting from a mono-crystalline p-type silicon wafer. An intrinsic a-Si:H buffer layer is deposited on the whole flat back side of the wafer by PECVD. Then, an interdigitated structure, of both p-type and n-type doped a-Si:H layers, is deposited through a comb mask. Through the same mask, properly aligned, the metal grid lines are evaporated. Finally, on the untextured front, surface, an a-Si:H/SiNx double layer is deposited in a PECVD reactor.

### Introduction

To combine the strength of both the technologies described above, we present an innovative cell design: a back contact and back junction cell where both the emitter and the back surface field are formed by an amorphous/crystalline silicon heterostructure, and the grid-less front surface is passivated by a double layer of amorphous silicon and silicon nitride, which also provides a good anti-reflection coating.

Here we present the initial results on untextured p-type monocrystalline silicon wafers. We show that the uniformity of the deposited amorphous silicon layers is not influenced by the mask-assisted deposition process and that the alignment is industrially feasible. Finally we analyze the results by individuating ways of improvement. We have named this device: BEHIND Cell (Back Enhanced Heterostructure with INterDigitated contacts Cell).

### EXPERIMENTAL

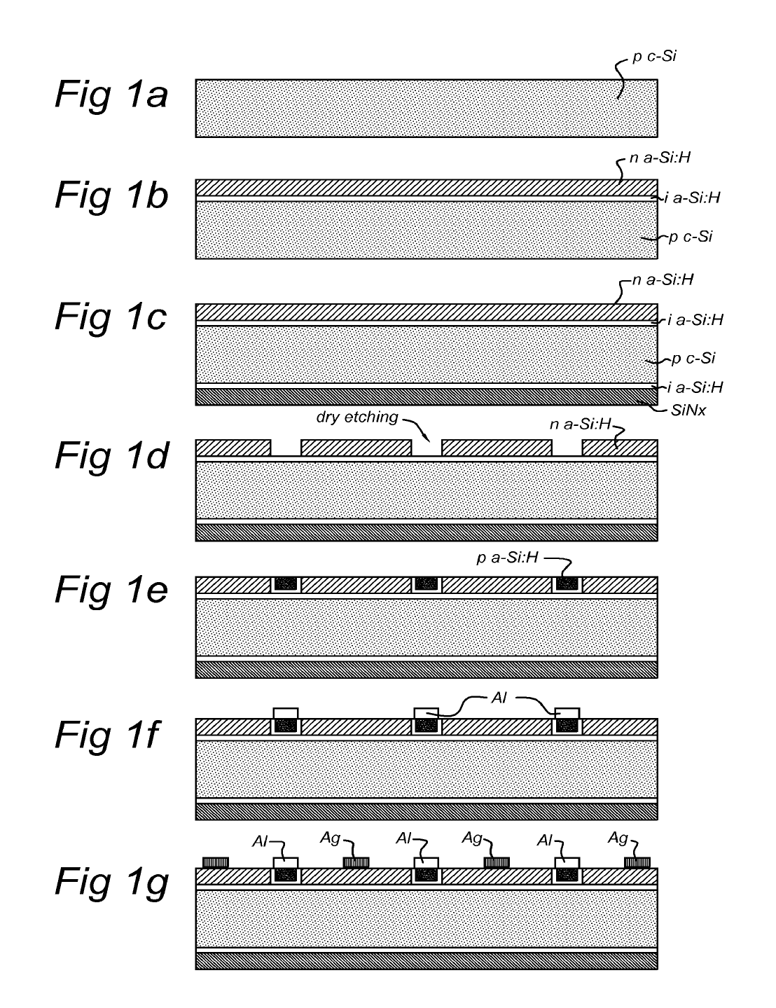

FIG. 1a: We have fabricated our BEHIND Cells using FZ, <100> oriented, 0.5 Ωcm, p-type doped, 250 μm thick, 4 inch diameter, one side polished crystalline silicon wafers. In an embodiment, the polished side is used as the back side of the device. It is noted that alternatively, the non-polished side may be used as back side.

As shown in FIG. 1b: the wafer, after a standard RCA clean and 1% HF dip, has been introduced in a 13.56 MHz direct Plasma Enhanced Chemical Vapor Deposition (PECVD) system to deposit a 5 nm thick intrinsic a-Si:H buffer layer and 15 nm thick n-type doped a-Si:H over its whole polished side at the following conditions:

(1) i a-Si:H layer: RF power density=28 mW/cm²; T=300° C.; P=300 mTorr; Gas flow=40 sccm SiH₄. (2) n a-Si:H layer: RF power density=28 mW/cm²; T=300° C.; P=300 mTorr; Gas flows: 10 sccm PH₃/SiH₄ 5%; 40 sccm SiH₄. To reduce interface damages between the two amorphous films we have grown intrinsic and n-doped layers in the same chamber, avoiding interruption of glow discharge.

FIG. 1c: The wafer is turned over to deposit the passivation/antireflection coating, since this side will be the front surface of the solar cell. To this aim we adopt the amorphous/silicon-nitride (a-Si:H/SiNₓ) double layer on the basis of previous experience, since it has demonstrated to perform better passivation of crystalline silicon surface with respect to the SiNₓ alone [11]. After a native oxide removal in a 1% HF wet bath, the double layer is deposited in the following conditions:

(3) i a-Si:H layer: RF power density=28 mW/cm², T=250° C., P=750 mTorr, Gas flow=120 sccm of 5% SiH₄ diluted in Ar. (4) SiNₓ layer: RF power density=200 mW/cm², T=250° C., P=750 mTorr, 1.66 as NH₃/SiH₄ gas flows ratio. Choosing thicknesses of 10 nm and 70 nm for a-Si:H and SiNₓ respectively, we have also ensured the best antireflection against sun spectrum.

FIG. 1d: For the p-type back side contact a particular mask has been fabricated from a Molybdenum foil, 150 μm thick, on which a comb shape grid has been opened focusing a Nd-YAG laser at a wavelength of 1064 nm. From the geometrical point of view we have dimensioned the distance between two adjacent fingers of the interdigitated combs supposing a diffusion length of minority photogenerated carriers in the order of 400 μm. This mask has been fixed by a particular holder on the n-type a-Si:H covered crystalline wafer, then a dry etching procedure using NF₃ gas has been performed to remove the n-type a-Si:H portion not covered by the mask, using the following conditions set up on the basis of previous experiences [12]: RF power density=400 mW/cm²; T=25° C.; P=50 mTorr, Gas flow=48 sccm NF₃.

FIG. 1e: At the end of the etching process the metallic mask has been not removed and the process has been continued in the same PECVD system. To ensure an isolation between the n a-Si:H edges and the p a-Si:H before this last layer we deposit a very thin intrinsic buffer layer of about 5 nm in the conditions above reported at point (1). Then the p-type has been deposited through the mask in the following conditions: (5) n a-Si:H layer: RF power density=28 mW/cm²; T=300° C.; P=300 mTorr; Gas flows: 6 sccm of B₂H₆; 40 sccm SiH₄. The thickness of this layer has been fixed at 15 nm.

FIG. 1f: Keeping the metallic mask still held on the sample we have evaporated a 2 μm thick of Al on the p-type a-Si:H.

FIG. 1g: Then a second mask is applied for evaporating the metal contact over the n-type a-Si:H layer. In an embodiment, the application of the second mask is performed by the mask that was used in the preceding stages as illustrated in FIGS. 1d-1f after a rotation over 180 degree of the mask.

Using this mask, we have evaporated the 2 μm thick Ag metal contact, over the n-type a-Si:H layer. The total area of the device is 6.25 cm². A schematic view of the entire process is shown in FIG. 1. At this stage the BEHIND Cell has been characterized in terms of current voltage (I-V), both in dark and AM1.5G conditions, reflectance and Quantum Efficiency (IQE internal quantum efficiency; EQE external quantum efficiency). As we will discuss in the next section, to reduce the series resistance we have irradiated the Al contact using a Q-switched Nd-YAG laser following the comb pattern with a PC controlled XY stage able to move the substrate at 10 mm/s under the beam. The laser has been used in the following conditions on the base of previous work [13]: wavelength at 1064 nm, mode TEM₀₀, power 320 mW, repetition rate 1 KHz.

In the above sequence of processing steps, the surface passivating antireflection coating [as shown above with reference to FIG. 3 under (3)] may also be deposited before the second conductivity type a-Si or after the first conductivity type a-Si have been deposited.

### RESULTS AND DISCUSSION

Every time someone thinks about a solar cell with both rear side contacts quickly realizes that the large number of steps and masks needed will be not appealing for the PV manufacturing. Therefore each new process in this kind of field should be simplified as much as possible. Moreover looking forward at thinner crystalline silicon wafers low thermal budget process should be preferred.

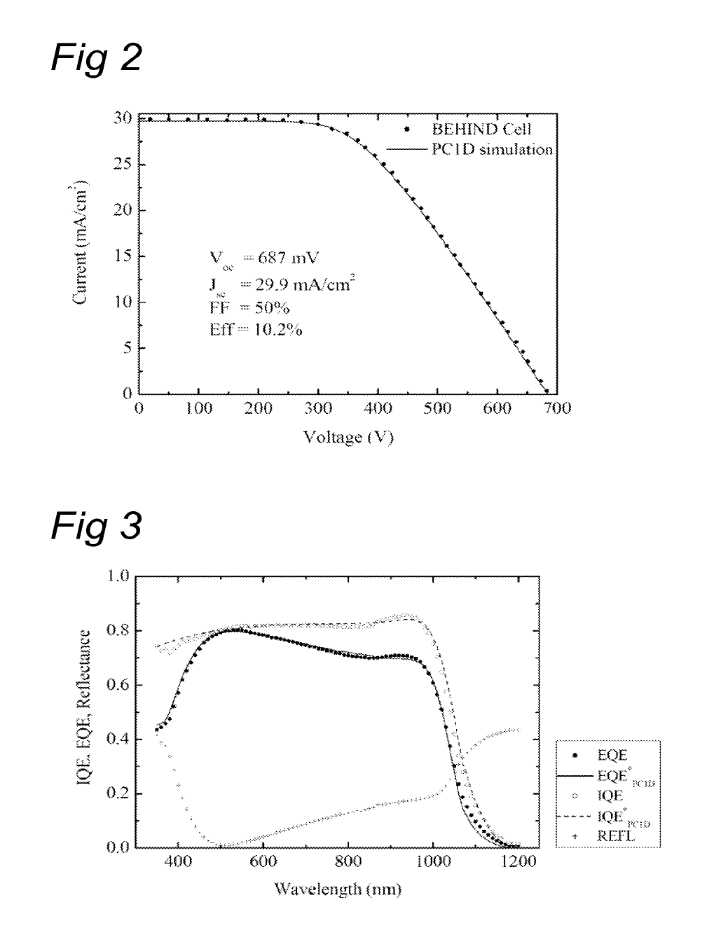

Our approach on BEHIND Cell fabrication has been focused on both issue, indeed, as detailed in the previous section, the maximum temperature of the entire process does not exceed 300° C. and only one metal mask has been involved in the process and its realignment, needed to obtain the two opposite and interdigitated combs, has been not very critical, due to the wide n-type a-Si emitter, extended also between the entire distance between two Al fingers. In turn the p-type contact has been revealed more critical. Indeed, particular care has been taken to the etching time to avoid total removal of the intrinsic buffer layer, causing damages and fluorine radicals contaminations at the silicon surface. After trial and error procedure we have estimated 30 s sufficient to remove about 15 nm that corresponds to the n-layer. Moreover when the dry etching is performed through a thick metallic mask only leaned on the surface of sample, proximity effect occurs along the edges of the opened pattern that limits the pattern transfer underneath as well as the expected etch rate, even if anisotropic etching is adopted. The conformal deposition of the subsequent intrinsic buffer layer deposited before the p-type a-Si:H layer has been useful to reduce unwanted shunt effects between the two a-Si:H doped layers. This has been confirmed by the high open circuit voltage (Voc) measured under the AM1.5G: 687 mV, as reported in FIG. 2. This high Voc value also confirms that the uniformity of the deposited amorphous silicon layers is not influenced by the mask-assisted deposition process and that the alignment is feasible. Of course the obvious advantage of this kind of structure is the absence of shadowing by a front metal grid. This, in principle, should reflect in high short circuit value (Jsc), with respect to the conventionally front grid contacted solar cells. But, as first result, Jsc has not exceeded 30 mA/cm2, as reported in FIG. 2 and also confirmed integrating the EQE, reported in FIG. 3, over the sun spectrum. To get better inside the limiting factor on photocurrent, we have performed a simulation by PC1D [14] simplifying our BEHIND Cell into a one dimensional crystalline silicon based solar cell, having back side emitter, and taking into account the reflectance profile of the front side as measured on the cell and reported in FIG. 3. The photocurrent of this cell is mainly due to electron diffusion in the crystalline silicon base plus a small contribute by depletion region. The n-type emitter has been dimensioned by 5.1017 cm-3 uniformly doped thin film having a-Si:H absorption, =1.10-9 cm2/V and Egap=1.65 eV, as expected for n-type doped a-Si:H. The front side of the device has been not textured and the surface passivation has been ensured by a double layer of SiNx/a-Si:H that, even if represents a good choice for crystalline silicon passivation [11], still presents a drawback due to a-Si:H absorption in the high energy photons of the sun spectrum. This, in principle, can be reduced increasing the gap of the a-Si:H with hydrogen dilution during the thin film growth. The simplified model of the cell has almost fitted the experimental EQE as well as the IQE data, except for the region of higher energy photons, since the simulation does not account for the passivation/antireflection coating absorption. To get better, at the end of EQE calculation, the data have been reduced, at each wavelength, by the a-Si:H thin layer absorption as follows:

EQE_{PC1D}*(λ)=EQE_{PC1D}(λ)·e^{-α}^{_{aSi:H}}^{(λ)·d} (1)

where α_{aSi:H(λ)} is the aSi:H absorption coefficient and EQE_{PC1D(λ)} is the EQE data as calculated by PC1D. By choosing a thickness d=2 nm it is possible to obtain the best fit of the EQE data in the spectrum region of higher energy photons, as reported in FIG. 3 as continuous and dashed line for EQE and IQE data respectively. From the fitting procedure we have deduced a front surface recombination S_{f} of 80 cm/s and a diffusion length L_{d} of 500 μm and the internal reflectance from the back side Rb is about 50%, while the recombination velocity at the back side is less relevant due to the μτ of the a-Si:H. We remark that during the EQE measurements a spot size of 35 mm² of monochromatic light has been used, that is much bigger than the finger dimensions of the interdigitated contacts. Therefore the effect of different depletion depth of region closer to the n-type emitter and region closer to the p-type contact has been averaged. Moreover the evidence of a swelling in the EQE as well as IQE data in the spectral region between 900 nm and 950 nm, ensures a good charge photogeneration also in the depletion region, confirming the wide extension of emitter region. Starting from the parameter values fixed to obtain the data fit, it is possible simulate how to reach highest IQE values. To this aim, we have found that Sₙ of 10 cm/s and a Lₙ of 1 mm or a wafer thickness reduction down to 170 μm are needed as well as the back reflectance have to be improved. While these values can be reached having more care in substrate preparation, as demonstrated by the same group in other work [13], actually the most serious problem of the BEHIND Cell is the high series resistance that strongly reduces the fill factor (FF). This problem mainly arises from the p-type a-Si:H/p-type a-Si:H contact. Indeed, as detailed elsewhere [14], due to the relevant band offset between the two valence band of p-type c-Si and p-type a-Si:H, the way to extract charge is a tunneling mechanism that can be obtained reducing the thicknesses of p-type a-Si:H as well as i a-Si:H layers and introducing alternative method to increase the conductivity of the p-type a-Si:H layer. Maybe, in our case, these thicknesses have been thicker than expected, since the necessity to avoid shunts between the two amorphous doped layers has wrongly induced to deposit thicker i-a-Si:H layer. Indeed, before laser treatment, the current of the cell has been completely dominated by the very high series resistance. To verify these arguments we have performed a laser treatment over the Al comb, knowing that this treatment is able to promote, in the right conditions, Al and Boron (being within the p-type a-Si:H material) diffusion into the crystalline base, producing a lower resistivity contact, even if in a narrow region. Therefore the I-V curve collected under AM1.5G at room temperature, reported in the FIG. 2, refers to the cell measured after laser treatment. In the same figure also the simulation with PC1D as continuous line is reported. In this case the fit of experimental data has been obtained by introducing an external high series resistance. To reduce this value, a large number of fingers should be introduced per square centimeter and a treatment to increase the n-type layer conductivity, forming a thin CrSi layer on it, can be really useful of the n-type amorphous emitter [16].

Even though the presented results can be considered preliminary and several technological aspects need to be optimized, they are very encouraging considering that this process is, up to now, the first tentative to introduce the a-Si:H/c-Si heterojunction to produce solar cells at very low temperature having both rear side contacts.

Here we have shown the BEHIND Cell as an innovative design of the a-Si:H/c-Si heterostructure solar cell. It is a back contacted and back junction cell, where both the emitter and the back contact are formed by amorphous/crystalline silicon heterostructure, and the grid-less front surface is passivated by a double layer of amorphous silicon and silicon nitride (a-Si:H/SiNₓ), which provides a good anti-reflection coating. We remark that only one metallic mask has been used in the entire fabrication process, demonstrating that the mask-assisted deposition of a-Si:H layer is feasible. With the aid of a PC1D model we have deduced the properties of transport and recombination that affect the photocurrent and we have addressed the way for future improvements. Even several technological aspects have to be optimized, such as the high value of series resistance that strongly limits the efficiency of the cell, a Voc of 687 mV has been reached that can be considered a good starting point to continue to develop this low temperature process useful to reduce the PV manufacturing cost.

Some alternative embodiments will be appreciated by the skilled person:

finishing depositions of the junctions (first and second conductivity type a-Si layers) on the one side, before depositing the surface passivating antireflection coating on the other side,

depositing the surface passivating antireflection coating, before the depositions of the first and second conductivity type a-Si:H layers,

adding a treatment such as wet chemical oxidation or thermal oxidation before the deposition of the anti-reflection layer, to enhance the surface passivating properties of the anti reflection layer,

extending the process with, for example, depositions of isolation layers, patterning of those isolation layers, and/or deposition of metallic patterns (such as busbars) on top of the described device, for interconnection purposes,

texturisation of the front side; e.g. by alkaline liquid texturisation (so-called random pyramid etching) or by dry etching. The latter can be done, for example, in situ before the surface passivating antireflection layer.

Although specific embodiments of the invention have been described, it should be understood that the embodiments are not intended to limit the invention. The invention may embody any further alternative, modification or equivalent, only limited by the scope of the appended claims.

### LIST OF REFERENCES

### 1-17

[1] http://sunpowercorp.com
[2] http://www.sanyo.co.jp/clean/solar/hit_e/hit.html
[3] W. Mulligan and R. Swanson, Proc. of 13th NREL Crystalline Silicon Workshop, Colorado, (2003) 30.
[4] D. Rose, O. Koehler, N. Kaminar, B. Mulligan, and D. King, Proc. of 4th World Conference Photovoltaic Energy Conversion, (2006) 2018.
[5] Eiji Maruyama, Akira Terakawa, Mikio Taguchi, Yukihiro Yoshimine, Daisuke Ide, Toshiaki Baba, Masaki Shima, Hitoshi Sakata, and Makoto Tanaka, Proceeding of WCPEC-4, Hawaii, 2006; 1455.
[6] W. P. Mulligan, D. H. Rose, M. J. Cudzinovic, D. M. De Ceuster, K. R. McIntosh, D. D. Smith, and R. M. Swanson, Proc. of IXX European Photovoltaic Solar Energy Conference (2004) 387.
[7] W. P. Mulligan, M. A. Carandang, M. Dawson, D. M. De Ceuster, C. N. Stone, and R. M. Swanson, Proc. of XXI European Photovoltaic Solar Energy Conference (2006) 1301.
[8] Richard M. Swanson, Proceeding of 20th EU-PVSEC, Barcelona, 2005; 584.
[9] M. Taguchi, K. Kawamoto, S. Tsuge, T. Baba, H. Sakata, M. Morizane, K. Uchihashi, N. Nakamura, S. Kiyama and O. Oota, Prog. Photovolt: Res. Appl. 8 (2000) 503.
[10] E. Maruyama, A. Terakawa, M. Taguchi, Y. Yoshimine, D. Ide, T. Baba, M. Shima, H. Sakata, and M. Tanaka, Proc. of 4th World Conference Photovoltaic Energy Conversion, (2006) 1455.
[11] M. Taguchi, A. Terakawa, E. Maruyama and M. Tanaka, Prog. Photovolt: Res. Appl. 3 (2005) 481.
[12] M. Tucci, L. Serenelli, S. De Iuliis, M. Izzi to be published in Thin solid Film.
[13] M. Tucci, L. Serenelli, S. De Iuliis, E. Salza, L. Pirozzi. Proc. of XXI European Photovoltaic Solar Energy Conference (2006) 1250.
[14] L. Kreinin, N. Bordin, J. Broder, N. Eisenberg, M. Tucci, E. Talgorn, S. De Iuliis, L. Serenelli, M. Izzi, E. Salza, L. Pirozzi. Proc. of XXI European Photovoltaic Solar Energy Conference (2006) 855.
[15] PC1D version 5.3 P. A. Basore, D. A. Clugston University of New South Wales (1998).
[16] M. Tucci, L Serenelli, S De Iuliis, D Caputo, A Nascetti, G de Cesare. Proc. of XXI European Photovoltaic Solar Energy Conference (2006) 902.
[17] M. Tucci, G. de Cesare, Journal of Non Crystalline Solids 338 (2004) 663.

1. Method for manufacturing a solar cell, comprising:
providing a first conductivity type doped crystalline silicon wafer;
depositing on one side of the wafer a first intrinsic a-Si:H buffer layer, followed by an second conductivity type doped a-Si:H layer;
turning over the wafer and depositing on a gridless side opposite the one side a suface passivating anti-reflection coasting;
applying a first mask having a grid opening on the second conductivity type doped a-Si:H covered surface of the wafer;
dry etching to remove the second conductivity type doped a-Si:H layer not covered by the first mask; and
while maintaining the first mask in position:
depositing a second intrinsic buffer layer of a-Si:H, and
depositing a first conductivity type doped a-Si:H layer
wherein the second intrinsic buffer layer is arranged as an isolation between the edges of the second conductivity type doped a-Si:H layer and the first conductivity type a-Si:H layer.

2. Method for manufacturing a solar cell according to claim 1, comprising:
depositing a first contact material layer on the first conductivity type doped a-Si:H layer, while maintaining the first mask in position.

3. Method for manufacturing a solar cell according to claim 1, comprising:
applying a second mask and depositing through the second mask a second contact material layer on the second conductivity type doped a-Si:H layer

4. Method for manufacturing a solar cell according to claim 1, wherein the first mask has a comb shaped grid opening.

5. Method for manufacturing a solar cell according to claim 3, wherein applying the second mask is performed by rotating the first mask over 180 degrees on the wafer.

6. Method for manufacturing a solar cell according to claim 1, wherein the first conductivity type is p-type and the second conductivity type is n-type.

7. Method for manufacturing a solar cell according to claim 1, wherein the first conductivity type is n-type and the second conductivity type is p-type.

8. Method for manufacturing a solar cell according to claim 2, wherein the first contact material layer on the first conductivity type doped a-Si:H layer is Al.

9. Method for manufacturing a solar cell according to claim 3, wherein the second contact material/layer on the second conductivity type doped a-Si:H layer is Ag.

10. Method for manufacturing a solar cell according to claim 3, further comprising depositing a first contact material layer on the first conductivity type doped a-Si:H layer, while maintaining the first mask in position, and wherein the first contact material/layer on the first conductivity type doped a-Si:H layer and the second contact material/layer on the second conductivity type doped a-Si:H layer are comb shaped.

11. Method for manufacturing a solar cell according to claim 3, further comprising depositing a first contact material layer on the first conductivity type doped a-Si:H layer, while maintaining the first mask in position, and wherein the first contact material layer on the first conductivity type doped a-Si:H layer and the second contact material/layer on the second conductivity type doped a-Si:H layer are interdigitated.

12. Method for manufacturing a solar cell according to claim 1, wherein the surface passivating anti-reflection coating is an a-Si:H/SiNx double layer.

13. Method for manufacturing a solar cell according to claim 1, wherein the one side of the crystalline silicon wafer is a polished side of the wafer.

14. Method for manufacturing a solar cell according to claim 1, wherein the distance between adjacent fingers of the interdigitated combs is dimensioned supposed to the diffusion length of minority photo generated carriers.

15. Method for manufacturing a solar cell according to claim 14, wherein the diffusion length is in the order of 400 μm.

16. Method for manufacturing a solar cell according to claim 1, wherein processing is performed at temperature below 300° C.

17. Method for manufacturing a solar cell comprising an emitter and a back surface field as rear-junctions with back side contacting, and a grid-less front surface passivated by a surface passivating anti-reflection coating, the emitter and the back surface field both formed by a a-Si:H/c-Si heterostructure, the back side contacting of the emitter being interdigitated with the backside contacting of the back surface field, and on the opposite side of the wafer a surface passivating anti-reflection coating, the method, comprising:
providing a first conductivity type doped crystalline silicon wafer;
depositing on one side of the wafer a first intrinsic a-Si:H buffer layer, followed by an second conductivity type doped a-Si:H layer;
turning over the wafer and depositing on a gridless side opposite the one side a suface passivating anti-reflection coasting;
applying a first mask having a grid opening on the second conductivity type doped a-Si:H covered surface of the wafer;
dry etching to remove the second conductivity type doped a-Si:H layer not covered by the first mask;
while maintaining the first mask in position, depositing a second intrinsic buffer layer of a-Si:H, and depositing a first conductivity type doped a-Si:H layer, wherein the second intrinsic buffer layer is arranged as an isolation between the edges of the second conductivity type doped a-Si:H layer and the first conductivity type a-Si:H layer;
depositing a first contact material layer on the first conductivity type doped a-Si:H layer to form a contact to the first conductivity type doped a-Si:H layer, while maintaining the first mask in position; and
applying a second mask and depositing through the second mask a second contact material layer on the second conductivity type doped a-Si:H layer to form a contact to the second conductivity type doped a-Si:H layer.

18. Method for manufacturing a solar cell according to claim 17, wherein the first mask has a comb shaped grid opening.

19. Method for manufacturing a solar cell according to claim 17, wherein applying the second mask is performed by rotating the first mask over 180 degrees on the wafer.

20. Method for manufacturing a solar cell according to claim 17, wherein the first contact material layer on the first conductivity type doped a-Si:H layer is Al.
